(19) United States
(12) Patent Application Publication
(10) Pub. No.: US 2008/0036070 A1
(43) Pub. Date: Feb. 14, 2008

(54) Bond Wireless Package

(75) Inventor: Samuel J. Anderson, Tempe, AZ (US)

Correspondence Address: GOODWIN PROCTER LLP;PATENT ADMINISTRATOR, EXCHANGE PLACE, BOSTON, MA, 02109-2881, US

(73) Assignee: GREAT WALL SEMICONDUCTOR CORPORATION, TEMPE, AZ (US)

(21) Appl. No.: 10/581,263

(22) PCT Filed: Dec. 1, 2004
(86) PCT No.: PCT/US04/40197

§ 371 Date: Apr. 16, 2007

Related U.S. Application Data
(60) Provisional application No. 60/526,926, filed on Dec. 3, 2003.

(51) Int. Cl. H01L 23/48

(52) U.S. Cl. 257/696; 257/E23.01

(57) ABSTRACT

There is provided herein exemplary embodiments of a semiconductor device constructed in accordance with the present invention. The device comprises: a semiconductor chip having a lateral power transistor device formed therein. The chip has an upper surface and source, drain and gate contact terminals on the upper surface thereof. Each of the source, drain and gate contact terminals have a conductive ball or pillar bump thereon. A metal lead frame spans the upper surface of the chip, the metal lead frame being in electrical contact with the conductive balls or pillar bumps. A capsule encases the chip and at least a portion of the metal lead frame such that opposite ends of the metal lead frame protrudes from opposite sides of the capsule.

### CROSS-REFERENCE TO RELATED APPLICATIONS

This application claims the benefit of priority to U.S. application Ser. No. 60/526,926, filed Dec. 2, 2003, the entire disclosure of which is hereby incorporated by reference as if set forth at length herein.

### STATEMENT REGARDING FEDERALLY SPONSORED RESEARCH OR DEVELOPMENT

Not applicable

### REFERENCE OF A “MICROFICHE APPENDIX”

Not applicable

### BACKGROUND OF THE INVENTION

1. Field of Invention

The present invention relates generally to semiconductor packaging technology and more particularly, to a bond-wireless semiconductor package and methods of making same.

2. Brief Description of the Prior Art

Early power MOSFETs were lateral device structures. Current flow between the source and drain terminals occurred laterally, parallel to the chip's top surface. The size of a lateral power MOSFET was dependent on both the minimum feature size of the photolithographic equipment in the semiconductor manufacturing facility and the blocking voltage requirement of the MOSFET.

Early photolithographic equipment used to construct a lateral power MOSFET was capable of minimum feature sizes on the order of 5-20 μm. The construction of a lateral power MOSFET requires the definition and relative placement of multiple regions, therefore the coarse photolithographic capability resulted in transistors of physically large sizes. For a lateral power MOSFET, the blocking voltage of the transistor is most commonly increased by increasing the separation between the gate and drain regions of the device. Blocking voltage requirements on the order of 100 V-1000 V requires a separation between gate and drain region of 5 μm to 100 μm, further increasing the size of early lateral power MOSFETs.

A discrete power device is typically a composite device that is constructed by interconnecting many transistors on a piece of silicon substrate. If the discrete power device consists of physically large transistors, such as the early lateral power MOSFETs, described above, then only a small number of transistors can be built on the device's silicon substrate and consequently, limits the on-resistance and electrical current capability of the device.

Early lateral discrete MOSFETs were generally not considered sufficiently cost-effective for high current switching power applications.

Vertical trench MOSFETs were introduced to overcome the physical size limitations of early lateral power MOSFETs and are the most common power MOSFET structure used today. The main improvement in the performance of the vertical trench power MOSFET results from the method in which the blocking voltage requirement is achieved. Similar to the lateral power MOSFET, the blocking voltage requirement is achieved by increasing the distance between the gate region and the drain. Since the drain of the vertical trench power MOSFET is the back of the wafer, this physical spacing is achieved by varying the thickness of the doped silicon layers beneath the surface. This no longer impacts the surface area of the elemental transistor cell.

Vertical trench MOSFETs, offer very low specific RDS(ON), but suffer from high gate charge and gate capacitance due to the inherent vertical trench gate structure. In a vertical trench MOSFET current flows vertically or perpendicular to the transistor's surface. The vertical trench power MOSFET benefits from reductions in the minimum feature size of the manufacturing facility, thereby reducing the elemental transistor size. However, within low voltage ranges below 30 V, the low channel resistance of trench MOSFET's is overshadowed by the parasitic resistance from the device substrate and package (mainly wirebond resistance).

In accordance with this invention, it has been recognized that with the reduction of minimum feature size of the photolithographic equipment and development of additional techniques lateral power MOSFETs can be constructed that are superior to the now dominant vertical trench power MOSFET.

In today's lateral power MOSFET, the minimum feature size of current advanced wafer fabs has been reduced to approximately 0.18 μm. Further reductions in minimum feature size are expected, driven by the requirements for high performance microprocessors and memory chips to pack billions of transistors on a single piece of silicon. Using 1 μm or smaller feature sizes results a substantial reduction in the lateral power MOSFET size. Depending on the voltage requirement of the device, the lateral power MOSFET can achieve on-resistance and current capability that is better than or almost equal to that of the vertical trench power MOSFET for the same chip size.

An important inherent advantage of the lateral power MOSFET is a significantly lower gate-drain capacitance. This allows a discrete power device to be used efficiently at high operating frequencies. Furthermore, the lateral power MOSFET, having all electrical terminals available on the top surface of the chip, lends itself to various wafer bumping packaging options. Wafer bumping of lateral power MOSFETs eliminates bond wires and the associated parasitic resistance and inductance. The reduction in parasitic resistance improves the RDSON of the packaged power MOSFET. The elimination of the inductance associated with bond wires improves the MOSFET's high frequency performance. Wafer bumping of lateral power MOSFETs also provides an efficient thermal conduction path between the top surface of the semiconductor chip, where the heat is generated, and the lead frame or thermal conductive material to which the chip is mounted. The efficient thermal conduction paths allows lateral bumped MOSFETs to operate at high power levels.

In a conventional semiconductor package containing a power MOSFET, the MOSFET makes electrical contact to the outside world using thin bond wires made of gold or aluminum of 1/1000 of an inch in diameter. These wires are “welded” to the surfaces of the MOSFET and also to terminations inside of the semiconductor package. However, the semiconductor package's bond wires add extra resistance to the package and are ineffective in their conduction of heat, thus creating problems in systems where power loss and heat dissipation are a concern.

As a result of the above limitations and the widespread use of vertical trench power devices, attempts have been made to develop bond wireless semiconductor packages containing semiconductor chips comprising vertical trench power devices. For example, U.S. Pat. No. 6,800,932 describes a semiconductor package “sandwich” containing a semiconductor chip comprising a vertical trench power MOSFET (“vertical trench chip”), a symmetrical lead frame electrically attached without wire bonds to the source and gate terminals on a topside of the vertical trench chip and a heat sink electrically attached without wire bonds to the drain terminal on the bottom side of the vertical trench chip.

Today's high frequency power management systems require power semiconductor packages having a combination of low static drain-source on resistance, high break-down voltage rating, low thermal resistance and high power dissipation. Unfortunately, these requirements are not being met by current vertical trench wire-bond or bond-wireless semiconductor packaging solutions.

Due to advances with lateral power devices, a lateral power MOSFET is particularly attractive for high frequency power management systems because of their low gate charge and low static drain-source on-resistance.

Therefore, there is a need for a bond-wireless semiconductor package containing a lateral power MOSFET having improved static drain-source on resistance, break-down voltage rating, thermal resistance and power dissipation. In certain embodiments, the bond-wireless semiconductor package can also have analog functions integrated into the MOSFET structure and bumped for bond wireless packaging or analog functions packaged using the bond wireless approach.

### SUMMARY OF THE INVENTION

The present invention addresses the aforementioned limitations of the prior art by providing, in accordance with one aspect of the present invention, an innovative metal interconnect and chip-scale packaging concept that overcomes the scaling limitation of a lateral power MOSFET by incorporating wafer bumping processes.

In accordance with another aspect of the present invention, there is provided herein exemplary embodiments of a semiconductor device constructed in accordance with the present invention. The device comprises: a semiconductor chip having a lateral power transistor device formed therein. The chip has an upper surface and source, drain and gate contact terminals on the upper surface thereof. Each of the source, drain and gate contact terminals have a conductive ball or pillar bump thereon. A metal lead frame spans the upper surface of the chip, the metal lead frame being in electrical contact with the conductive balls or pillar bumps. A capsule encases the chip and at least a portion of the metal lead frame such that opposite ends of the metal lead frame protrudes from opposite sides of the capsule.

In accordance with another aspect of the present invention, the balls comprise a conductive solder and the pillar bumps comprise a conductive solder and copper.

In accordance with another aspect of the present invention, the lateral power transistor device comprises a lateral power metal oxide field effect transistor.

In accordance with another aspect of the present invention, the lead frame comprises a conductive metal.

In accordance with another aspect of the present invention, the capsule comprises a electrically non-conductive molding compound.

These and other aspects, features and advantages of the present invention will become better understood with regard to the following description, appended claims, and accompanying drawings.

### BRIEF DESCRIPTION OF THE DRAWINGS

Exemplary embodiments of the present invention are now briefly described with reference to the following drawings:

FIG. 1 depicts one aspect of the present invention in accordance with the teachings presented herein.

FIG. 2 depicts a second aspect of the present invention in accordance with the teachings presented herein.

FIG. 3 depicts a third aspect of the present invention in accordance with the teachings presented herein.

FIG. 4 depicts a fourth aspect of the present invention in accordance with the teachings presented herein.

FIG. 5 depicts a fifth aspect of the present invention in accordance with the teachings presented herein.

FIG. 6 depicts a sixth aspect of the present invention in accordance with the teachings presented herein.

### DESCRIPTION OF THE INVENTION

The aspects, features and advantages of the present invention will become better understood with regard to the following description with reference to the accompanying drawings. What follows are preferred embodiments of the present invention. It should be apparent to those skilled in the art that the foregoing is illustrative only and not limiting, having been presented by way of example only. All the features disclosed in this description may be replaced by alternative features serving the same purpose, and equivalents or similar purpose, unless expressly stated otherwise. Therefore, numerous other embodiments of the modifications thereof are contemplated as falling within the scope of the present invention as defined herein and equivalents thereto.

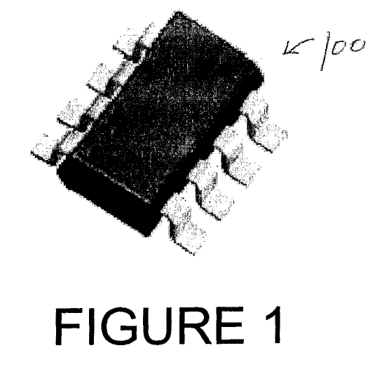

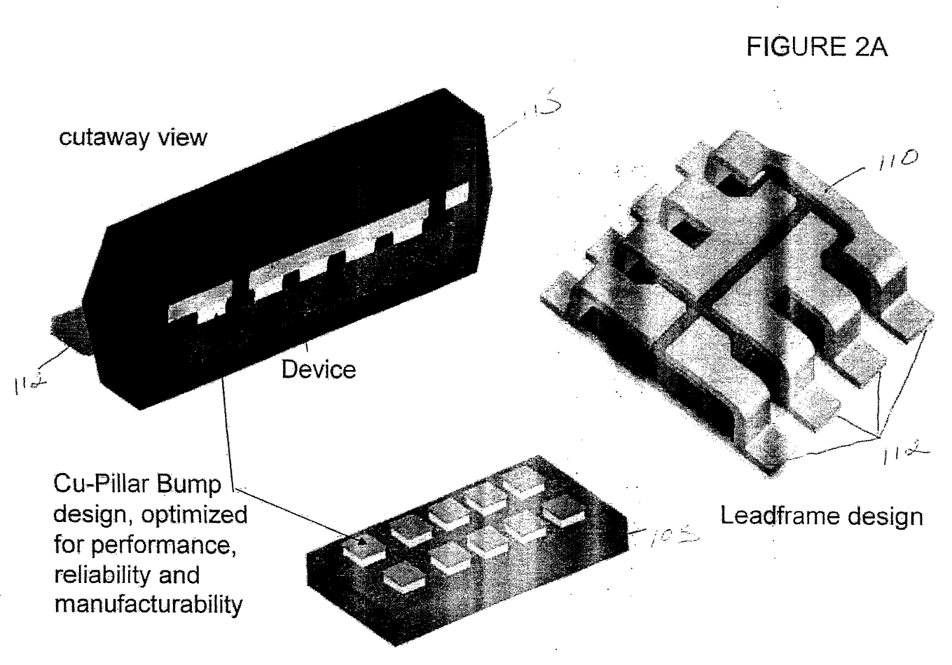

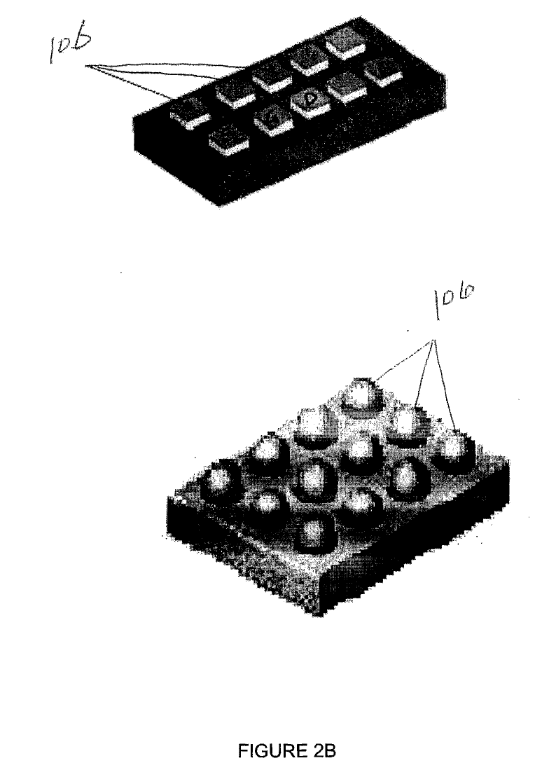

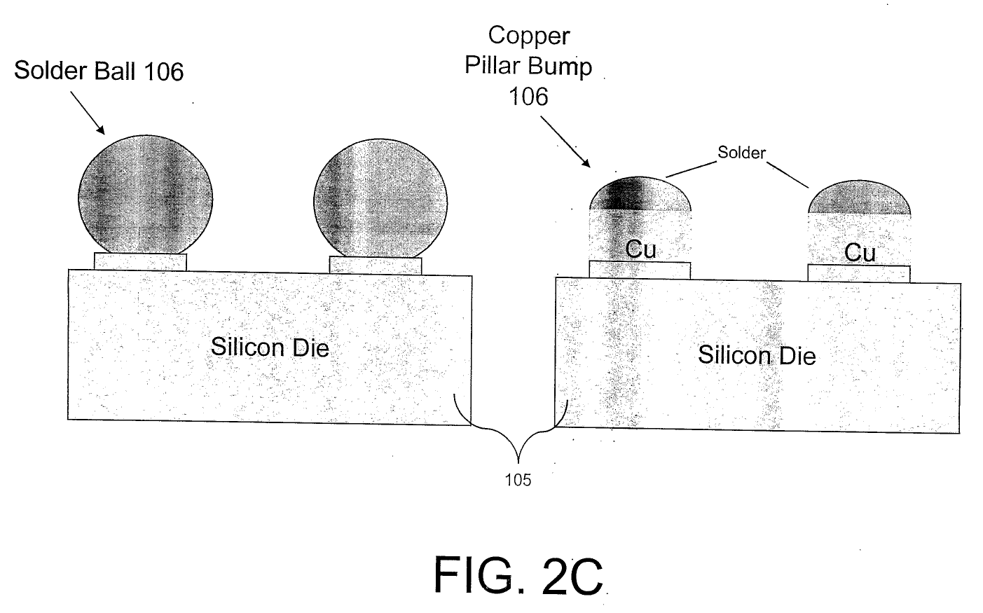

FIGS. 1 and 2 depict two views of an exemplary embodiment of a bond-wireless semiconductor package 100 according to the present invention. The bond-wireless semiconductor package 100 includes two essential structures: a semiconductor chip 105 and a lead frame 110. A capsule 115 is molded around the chip 105 and the lead frame 110 exposing portions of the lead frame 110 and creating external leads 112. The external leads 112 may be bent or formed to allow them to be connected to a flat surface such as circuit board.

In embodiments of the present invention, the semiconductor chip 105 comprises a three-terminal chip such as a lateral power MOSFET. The lateral power MOSFET includes a source terminal, a gate terminal, and a drain terminal on the top surface of the chip.

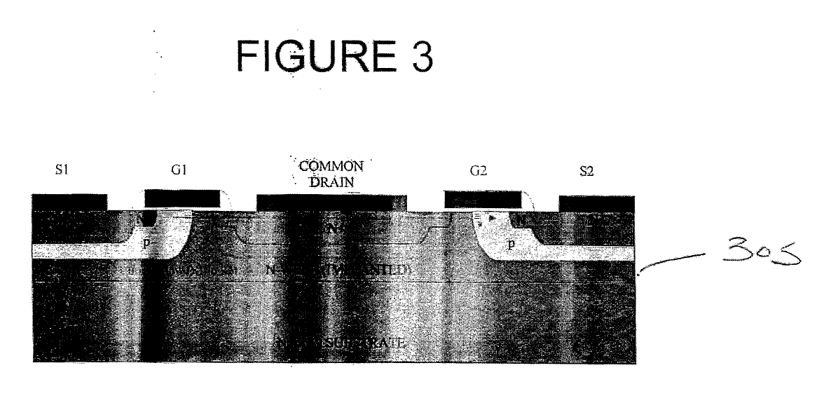

FIG. 3 depicts a novel semiconductor chip comprising a bi-directional lateral power MOSFET 305 that is particularly suited for use in the semiconductor chip package 100 of the present invention. The chip 305 is an interleaved common-drain lateral double—diffused MOSFET (LDMOS) structure. The chip 305 has a breakdown voltage (BVDSS) of greater than 20 V and a low on-resistance (RDSON) of 20Ωm at VGS of 4.5 V. The chip 305 has a chip footprint of 1.2 mm by 2.34 mm, has an ultra low FFOM of 85Ωmm2 and an ultra low package profile of less than 0.8 μm. The chip 305 is further described in U.S. patent application Ser. No. 10/601,121, and U.S. Provisional Patent Application Nos. 60/444,932 and 60/501,192, each of which is incorporated by reference in its entirety herein.

Referring back to FIGS. 2A-C, the semiconductor chip 105 also includes a conductive ball or pillar bump interconnect structure 106, the pillar bump preferably comprising copper. Each ball or pillar bump 106 connects to one or more sources, drains or gates on the chip 105.

The lead frame 110 is formed of a flat sheet of conductive metal such as copper and extends laterally over opposite edges of the chip 105. In this embodiment, the leads are symmetrical about an axis of the chip 105. The opposite ends of the leads are normally bent, preferably at the end of the manufacturing process, to form surfaces that can be electrically mounted to a flat object. In one example of the semiconductor chip package 100, the bumped semiconductor chip 105 is mounted to a lead frame 110 so that the drain region of the lateral power MOSFET comprising the semiconductor chip 105 contacts the lead frame 110. A conductive solder preferably comprising tin or epoxy is used to bond the balls or pillar bumps 106 corresponding to the source and gate regions of the MOSFET to inner portions of the lead frame 110.

Thereafter, the bumped semiconductor chip 105 and an inner portion of the lead frame 110 may be encapsulated in a non-conductive molding compound such as plastic to form the bond-wireless semiconductor chip package 100.

The bond-wireless semiconductor package 100 has several advantages over conventional wire bond vertical trench power MOSFET semiconductor packages. First, the bond-wireless semiconductor package 100 has 45% less thermal resistance and 75% less electrical resistance from drain terminal to source terminal than a conventional wire bond semiconductor package.

All semiconductor devices have some electrical resistance. When power MOSFETs are operating, that is, switching or otherwise controlling reasonable currents, they dissipate power as heat energy. If the device is not to be damaged by this, the heat must be removed from inside the device (usually from the drain-source channel in a power MOSFET) at a fast enough rate to prevent excessive temperature rise. Therefore, the shorter the thermal conduction path and larger contact area for a given semiconductor device the lower the thermal resistance.

In both lateral power and vertical trench power MOSFET configurations, the most heat is generated in the top surface region of the semiconductor chip. The metallic lead frame serves as a heat sink to facilitate thermal output from the package.

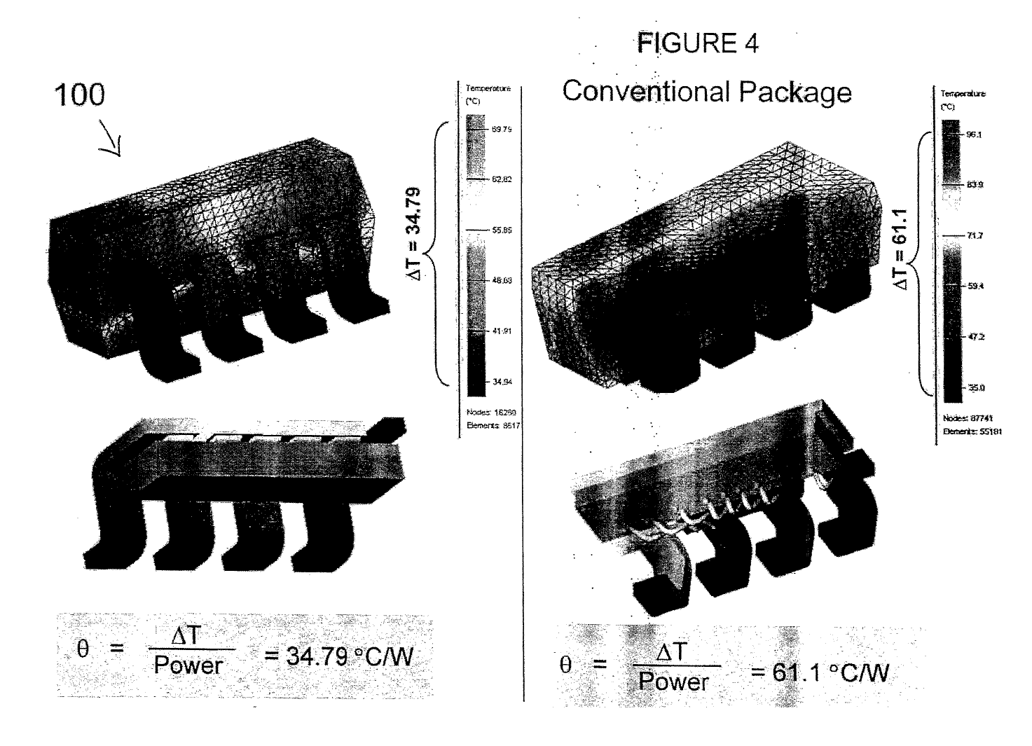

In a conventional wire bond vertical trench power MOSFET semiconductor package, wirebonds are connected to gate and source terminals on the top-side of the semiconductor chip and the lead frame is connected to the drain terminal on the bottom side of the chip. The heat generated at the top surface of the semiconductor chip remains in the package longer because it has a long path to travel, through the chip to the opposite side of the chip in order to leave the package via the metallic lead frame. In the present invention's bond-wireless semiconductor package 100, the heat producing top-side of the semiconductor chip is connected to the metallic lead frame via solder balls or copper pillar bumps. Thus, the heat has a short path to travel in order to leave the package. FIGS. 4A-B depict the thermal characteristics of the bond-wireless semiconductor package 100 of the present invention in contrast to a conventional wire bond vertical trench power MOSFET semiconductor package.

With respect to stresses, the self induced stress condition is better, between 25% and 75% less, with the bond-wireless semiconductor package 100 because operating temperatures are lower. However, stresses induced due to external temperature conditions are comparable between the two packages.

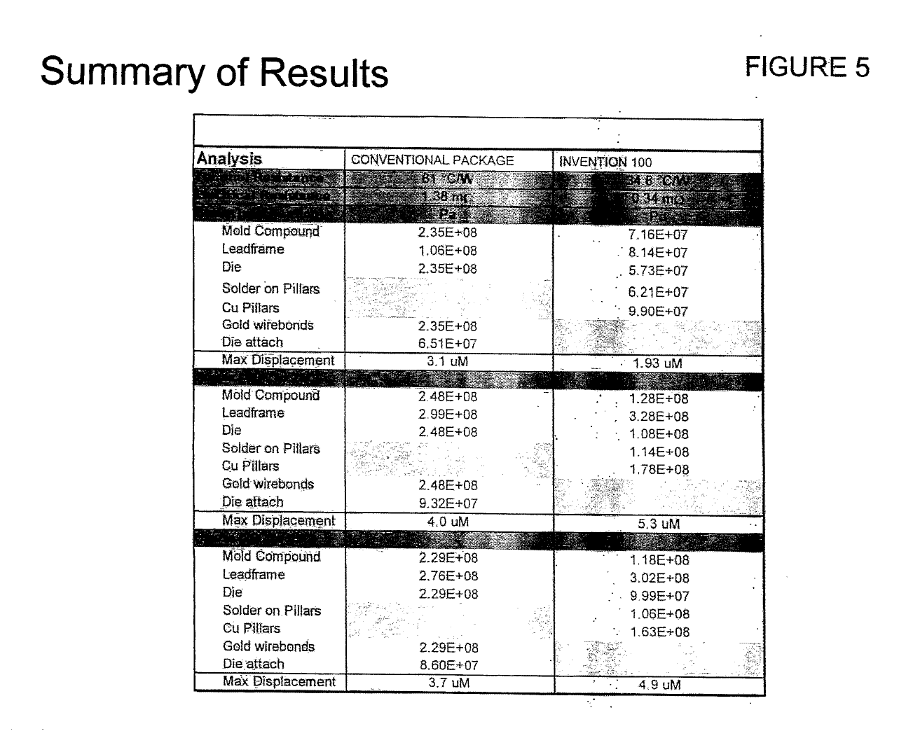

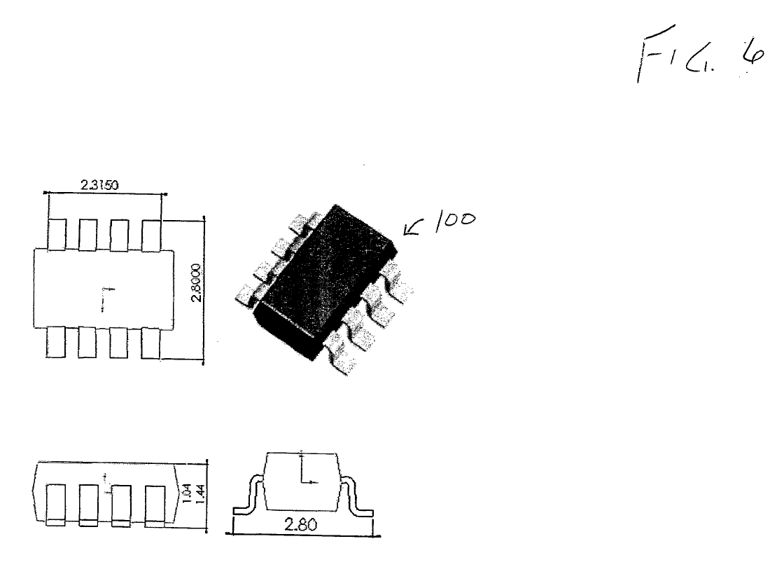

The bond-wireless semiconductor package 100 design uses a flip-chip chip bonding approach on a conventional lead frame. Proven copper pillar bumps technology is employed, allowing for a robust attachment and a simplified manufacturing process. In contrast, the conventional package requires up to 12 wire bond attachments per product. Wire bonds have historically been a yield and reliability concern due to the low fatigue strength of aluminum and high stress concentrations at the bond heal. The bond-wireless semiconductor package 100 has no such problems. FIG. 5 depicts a table summarizing the thermal, electrical and stress characteristics of the bond-wireless semiconductor package 100 as it compares favorably to a conventional wire bond package.

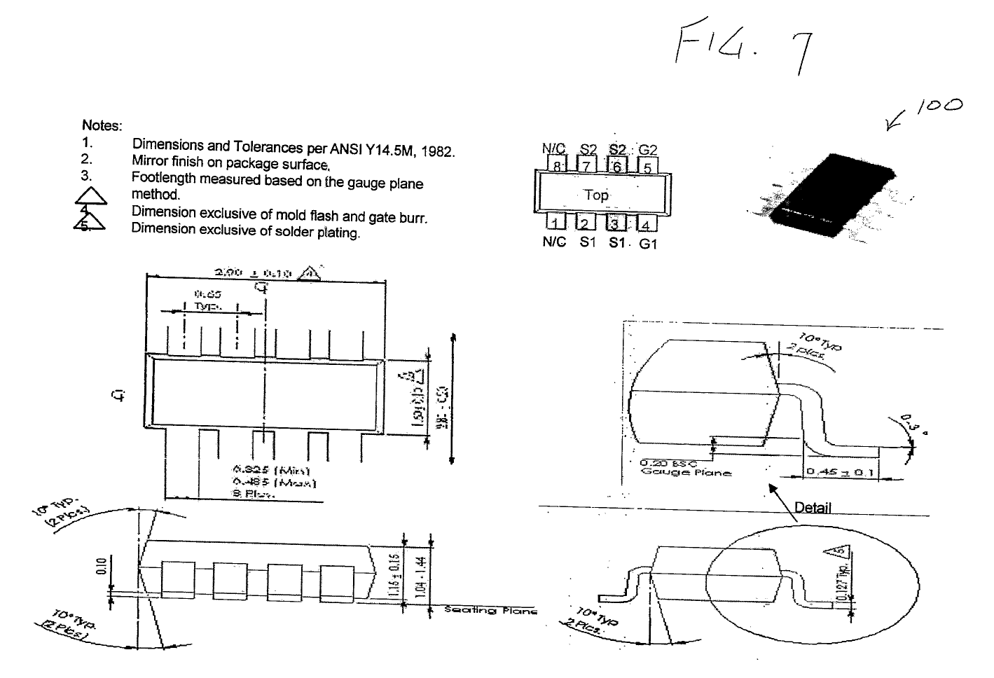

Finally, FIGS. 6 & 7 depict exemplary dimensions of an embodiment of the present invention's bond-wireless semiconductor package 100 with anticipated commercial potential.

### CONCLUSION

Having now described preferred embodiments of the invention, it should be apparent to those skilled in the art that the foregoing is illustrative only and not limiting, having been presented by way of example only. All the features disclosed in this specification (including any accompanying claims, abstract, and drawings) may be replaced by alternative features serving the same purpose, and equivalents or similar purpose, unless expressly stated otherwise. Therefore, numerous other embodiments of the modifications thereof are contemplated as falling within the scope of the present invention as defined by the appended claims and equivalents thereto.

For instance, the exemplary figures show an eight lead package as one embodiment of the present invention. As will be apparent to one skilled in the art, the present invention can be extended to packages with more or less than eight leads. Likewise, although, for instance, the figures depict a copper pillar bump, materials other than copper may be used. Further, the selection of suitable materials to be used as well as the size of the balls or pillar bumps would be apparent to one skilled in the art depending on factors such as conductivity, parasitic resistance, heat conduction and so on.

What is claimed is:

1. A semiconductor package, comprising:
semiconductor chip comprising a lateral power transistor device formed therein, said semiconductor chip having an upper surface and a terminal disposed on said upper surface, said terminal having a conductive bump selected from the group consisting of a ball bump and a pillar bump disposed thereon;
a metal lead frame spanning said upper surface of said semiconductor chip, said metal lead frame being in electrical contact with said conductive bump; and
a capsule encasing said semiconductor chip and at least a portion of said metal lead frame.

2. The semiconductor package as in claim 1 wherein the terminal is selected from the group consisting of a source terminal, a drain terminal, and a gate terminal.

3. The semiconductor package as in claim 1 wherein opposite ends of said metal lead frame protrude from opposite sides of said capsule.

4. The semiconductor package as in claim 1 wherein said pillar bump comprises copper and a conductive solder.

5. The semiconductor package as in claim 1 wherein said conductive ball comprises a conductive solder.

6. The semiconductor package as in claim 1 wherein said lateral power transistor device comprises a lateral power metal oxide field effect transistor.

7. The semiconductor package as in claim 1 wherein said lead frame comprises a conductive metal.

8. The semiconductor package as in claim 7 wherein said conductive metal comprises copper.

9. The semiconductor package as in claim 1 wherein said capsule comprises a non-conductive molding compound.

10. The semiconductor package as in claim 1 wherein said capsule comprises a plastic.

11. The semiconductor package as in claim 1 wherein said electrical contact is formed by conductive solder comprising at least one of tin and epoxy.

12. A semiconductor package, comprising:
monolithic semiconductor structure comprising a pair of lateral power transistor devices formed on a single semiconductor substrate, said semiconductor structure having an upper surface and a terminal disposed on said upper surface, said terminal having a conductive bump selected from the group consisting of a ball bump and a pillar bump disposed thereon;
a metal lead frame spanning said upper surface of said semiconductor structure, said metal lead frame being in electrical contact with said conductive bump; and
a capsule encasing said semiconductor structure and at least a portion of said metal lead frame.

13. The semiconductor package as in claim 12 wherein the terminal is selected from the group consisting of a source terminal, a drain terminal, and a gate terminal.

14. The semiconductor package as in claim 12 wherein opposite ends of said metal lead frame protrude from opposite sides of said capsule.

15. The semiconductor package as in claim 12 wherein said pillar bump comprise copper and a conductive solder.

16. The semiconductor package as in claim 12 wherein said conductive ball comprises a conductive solder.

17. The semiconductor package as in claim 12 wherein said lateral power transistor device comprises a lateral power metal oxide field effect transistor.

18. The semiconductor package as in claim 12 wherein said lead frame comprises a conductive metal.

19. The semiconductor package as in claim 18 wherein said conductive metal comprises copper.

20. The semiconductor package as in claim 12 wherein said capsule comprises a non-conductive molding compound.

21. The semiconductor package as in claim 12 wherein said capsule comprises plastic.

22. The semiconductor package as in claim 12 wherein said lateral power transistor device comprises an analog integrated circuit.

23. The semiconductor package as in claim 12 wherein said lateral power transistor device comprises an integrated MOSFET and analog circuit structure.

24. The semiconductor package as in claim 1 wherein said lateral power transistor device comprises an analog integrated circuit.

25. The semiconductor package as in claim 1 wherein said lateral power transistor device comprises an integrated MOSFET and analog circuit structure.

26. The semiconductor package as in claim 1, wherein the semiconductor package comprises a plurality of the semiconductor chips.

27. The semiconductor package as in claim 1, wherein the semiconductor chip comprises a plurality of the lateral power transistor devices formed therein.

28. The semiconductor package as in claim 1, wherein the lateral power transistor comprises a plurality of terminals disposed on said upper surface, the plurality of terminals comprising a source terminal, a drain terminal, and a gate terminal, each of said source, drain, and gate terminals having a conductive bump selected from the group consisting of a ball bump and a pillar bump disposed thereon.

29. The semiconductor package as in claim 12, wherein the semiconductor package comprises a plurality of the monolithic semiconductor structures.

30. The semiconductor package as in claim 12, wherein the monolithic semiconductor structure comprises a plurality of the pairs of lateral power transistor devices formed on a single semiconductor substrate.

31. The semiconductor package as in claim 12, wherein each of the lateral power transistor devices comprises a plurality of terminals disposed on said upper surface, the plurality of terminals comprising a source terminal, a drain terminal, and a gate terminal, each of said source, drain, and gate terminals having a conductive bump selected from the group consisting of a ball bump and a pillar bump disposed thereon.
